(19) United States
(12) Patent Application Publication
(10) Pub. No.: US 2014/0085317 A1
(43) Pub. Date: Mar. 27, 2014

(54) TRANSPARENT MULTI-LAYER STRUCTURE WITH TRANSPARENT ELECTRICAL ROUTING

(71) Applicants: Kristopher A. Lavery, San Jose, CA (US); David William Burns, San Jose, CA (US)

(72) Inventors: Kristopher A. Lavery, San Jose, CA (US); David William Burns, San Jose, CA (US)

(21) Appl. No.: 13/629,043

(22) Filed: Sep. 27, 2012

(51) Int. Cl. G06T 1/00; H05K 7/06; H05K 3/00; H05K 1/11

(52) U.S. Cl. CPC G06T 1/00; H05K 1/11; H05K 1/115; H05K 7/06; H05K 3/0058
USPC 345/501; 174/261; 174/266; 174/259; 361/760; 156/60

(57) ABSTRACT

This disclosure provides systems, methods and apparatus for providing a transparent multilayer structure having electrical connections between conductive components disposed throughout the structure. In one aspect, a thin transparent conductive adhesive is used to provide electrical connections between layers. These electrical connections can be made throughout the multilayer structure, even in portions of the structure that overlie a display in a display device, reducing the overall footprint of a display device including such a multilayer structure.

### TECHNICAL FIELD

This disclosure relates to multi-layer structures that can be positioned over displays or other objects to be viewed.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

In optical devices such as displays, the complexity of electrical routing between various layers of laminated structures is increased by the need to maintain high transmissivity and low visual artifacts for the portions of the layers overlying a display. Conventional layer-to-layer interconnection methods using metal traces, flex tapes, solder or anisotropic conductive film are limited generally to non-viewable portions near the periphery of the display. As more features such as touch panels and other sensors are added in front of the display, methods and structures for electrical connections between two or more layers are needed to reduce the number of external connections and flex tapes. Additionally, the substrates may have process temperature limitations below traditional solder eutectic temperatures, and processing methods that minimize the number of processing and assembly steps can be used to increase reliability and lower overall cost. Concerns for avoiding visual artifacts and obstructions of the viewing area of a display generally limits the types of structures, devices and features that may be positioned in front of the display.

### SUMMARY

The systems, methods and devices of this disclosure each have several innovative aspects, no single one of which is solely responsible for the desirable attributes disclosed herein.

One innovative aspect of the subject matter described in this disclosure can be implemented in a multi-layer device, including a substantially transparent first substrate, the first substrate including a first surface having a first conductive structure formed thereon, a substantially transparent second substrate, the second substrate including a first surface facing the first surface of the first substrate and having a second conductive structure formed thereon, and a transparent conductive adhesive layer adhering the first substrate to the second substrate, where the transparent conductive adhesive layer is disposed between at least a portion of the first conductive structure and at least a portion of the second conductive structure and provides a first conductive path therebetween.

In some implementations, the first conductive structure and the second conductive structure can include a transparent conductive material. In some implementations, the first conductive structure can include a first bond pad in electrical communication with a first conductive trace on the first surface of the first substrate, and where the second conductive structure includes a second bond pad in electrical communication with a second conductive trace on the first surface of the second substrate. In some implementations, the first conductive structure can include a conductive via extending through the first substrate.

In some implementations, the device can further include a third conductive structure on the first surface of the first substrate and a fourth conductive structure on the first surface of the second substrate, where the transparent conductive adhesive layer is disposed between at least a portion of the third conductive structure and at least a portion of the fourth conductive structure and provides a second conductive path therebetween, the second conductive path being electrically isolated from the first conductive path. In one further implementation, a first portion of the transparent conductive adhesive layer disposed between the first and second conductive structures can be separated from a second portion of the transparent conductive adhesive layer disposed between the third conductive structure and the fourth conductive structure. In another further implementation, a ratio of a resistance between the first and third conductive structures and a contact resistance between the first and second conductive structures can be greater than about 1,000,000.

In some implementations, the transparent conductive adhesive layer can include one or more polyfunctional adhesion promoters. In some implementations, the transparent conductive adhesive can include 3-aminopropyldiethoxysilane (APTES). In some implementations, the transparent conductive adhesive can include a material having a resistivity of between about 1,000 and about 10,000,000 ohm-cm. In some implementations, a thickness of a portion of transparent conductive adhesive between the first and second conductive structures can be less than about 50 nm. In some implementations, the contact resistance between the first conductive structure and the second conductive structure can be less than about 10,000 ohms.

In some implementations, the device can additionally include a display, where the display is viewable through the first transparent substrate and the second transparent substrate. In one further implementation, the display can include one of a light emitting diode based display, an organic light emitting diode based display, a liquid crystal display, a field emission display, an e-ink display, and an interferometric modulator based display. In another further implementation the first conductive path between the first conductive structure and the second conductive structure can overlie at least a portion of the display.

Another innovative aspect of the subject matter described in this disclosure can be implemented in a method of fabricating a multi-layer device, the method including providing a substantially transparent first substrate, the first substrate including a first surface having a first conductive structure formed thereon, providing a substantially transparent second substrate, the second substrate including a first surface facing the first surface of the first substrate and having a second conductive structure formed thereon, and adhering the first substrate to the second substrate using a transparent conductive adhesive disposed between the first conductive structure and the second conductive structure, where the transparent conductive adhesive provides an electrically conductive path between the first conductive structure and second conductive structure.

In some implementations, adhering the first substrate to the second substrate can include coating at least a portion of the first surface of the first substrate with the transparent conductive adhesive, and bonding the first surface of the first substrate to the first surface of the second substrate. In one further implementation the transparent conductive adhesive can be at least partially cured prior to bonding the first surface of the first substrate to the first surface of the second substrate. In another further implementation the transparent conductive adhesive can be cured after bringing the first surface of the first substrate into contact with the first surface of the second substrate. In another further implementation, coating at least a portion of the first surface of the first substrate with the transparent conductive adhesive can include forming discrete sections of transparent conductive adhesive on the first surface of the first substrate. In one still further implementation, the method can additionally include forming sections of a second material between the discrete sections of transparent conductive adhesive, where the second material is less conductive than the transparent conductive adhesive. In another still further implementation at least a portion of the space between the discrete sections of transparent conductive adhesive can be left unfilled.

In some implementations, adhering the first substrate to the second substrate can include applying pressure to hold the first and second substrates together. In a further implementation, adhering the first substrate to the second substrate can additionally include exposing the first and second substrates to a temperature between about 25° C. and about 200° C.

In some implementations, the method can additionally include performing a surface activation process to treat at least one of the first surface of the first substrate or the first surface of the second substrate prior to adhering the first substrate to the second substrate. In a further implementation, performing the surface activation process can include exposing at least one of the first surface of the first substrate or the first surface of the second substrate to an ultraviolet-ozone treatment or an oxygen plasma treatment.

Another innovative aspect of the subject matter described in this disclosure can be implemented in a display device, including a display, and a multilayer structure overlying the display, where the display is configured to be visible through a portion of the multilayer structure, the multilayer structure including a first substrate, where at least a portion of the first substrate overlying the display is substantially transparent, a second substrate, where at least a portion of the second substrate overlying the display is substantially transparent, and a transparent conductive adhesive disposed between at least a portion of the first substrate and the second substrate, where the transparent conductive adhesive forms a conductive path between at least a portion of a first conductive structure disposed on the first substrate and at least a portion of a second conductive structure disposed on the second substrate.

In some implementations, the multilayer structure can additionally include an external bond pad disposed on a first surface of the first substrate, and where the external bond pad is in electrical communication with the first conductive structure. In a further implementation, the multilayer structure can additionally include a third conductive structure disposed on the second substrate, where the second and third conductive structures are disposed on opposite sides of the second substrate, and where the second and third conductive structures are electrically connected to one another by a conductive via extending through the second substrate.

In some implementations, the conductive path between the first conductive structure and the second conductive structure can be located within the portion of the multilayer structure through which the display is configured to be visible.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1A shows an exploded view of a display device having an overlying multilayer laminate structure.

FIG. 1B shows an assembled view of the display device of FIG. 1A.

FIG. 2A shows an exploded view of a multilayer laminate structure that includes a pair of transparent substrates having electrically conductive structures formed thereon and bonded to one another by a thin transparent conductive adhesive material.

FIG. 2B shows an assembled view of the multilayer laminate structure of FIG. 2A.

FIG. 3A shows an exploded view of a multilayer laminate structure that includes a combination of conductive and substantially non-conductive transparent adhesives to adhere two substrates to one another.

FIG. 3B shows a cross-section of the assembled multilayer structure of FIG. 3A, taken along the line 3B-3B.

FIG. 4A shows an exploded view of a multilayer laminate structure that includes conductive vias that enable electrical connections through the component substrates.

FIG. 4B shows a cross-section of the assembled multilayer structure of FIG. 4A, taken along the line 4B-4B.

FIG. 5 shows a cross-section of a display device in which transparent conductive material provides an electrical connection between substrates within a multilayer assembly.

FIG. 6 shows an example of a flow diagram illustrating a manufacturing process for a multilayer assembly including transparent conductive material for providing an electrical connection between substrates within the assembly.

FIG. 7 is an isometric view illustration depicting two adjacent interferometric modulator (IMOD) display elements in a series or array of display elements of an IMOD display device.

FIG. 8 is a system block diagram illustrating an electronic device incorporating an IMOD-based display including a three element by three element array of IMOD display elements.

FIGS. 9A and 9B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A multi-layer structure, such as a multi-layer glass laminate, can include layers bonded together using a thin adhesive that is both optically transparent and electrically conductive. This adhesive can connect substantially transparent portions of conductive components such as electrical traces or through-glass electrical vias. The multi-layer glass laminate allows touch screens, front light and touch integrated panels, ground planes, and other electrical/electronic devices to be positioned in the region overlying the viewable area of an LCD or interferometric display, or any other device intended to be viewed through an overlying multilayer structure.

Particular implementations of the subject matter described in this disclosure can be implemented to realize one or more of the following potential advantages. Multi-layer transparent substrates with transparent conductive adhesive material forming interconnections between layers allow interconnection and external connection to electronic devices and/or components on one or more of the surfaces (internal or external) of the glass substrates, while retaining substantially high transparency through the glass. Because cross-layer connections are not constrained to the periphery of the device, the overall size of the multi-layer structure can be reduced due to possible reductions in the size of the peripheral area of the device. Electrically connecting devices or components on the transparent substrates can reduce the size of the border around many displays, and in some cases eliminate the need for a bezel on the user side of the display. Because connections can be made in the area overlying the display, traces that would otherwise need to extend around the periphery of the display can instead be made shorter by extending across the display, reducing the trace resistance and capacitance compared to longer traces.

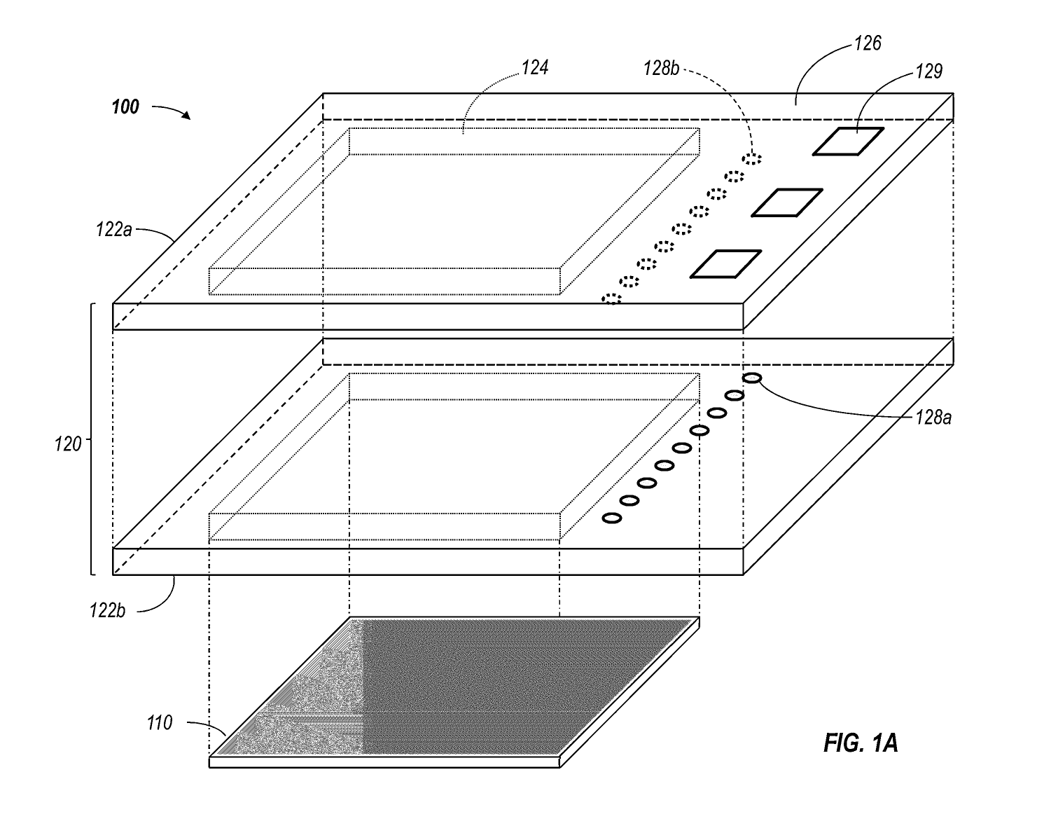

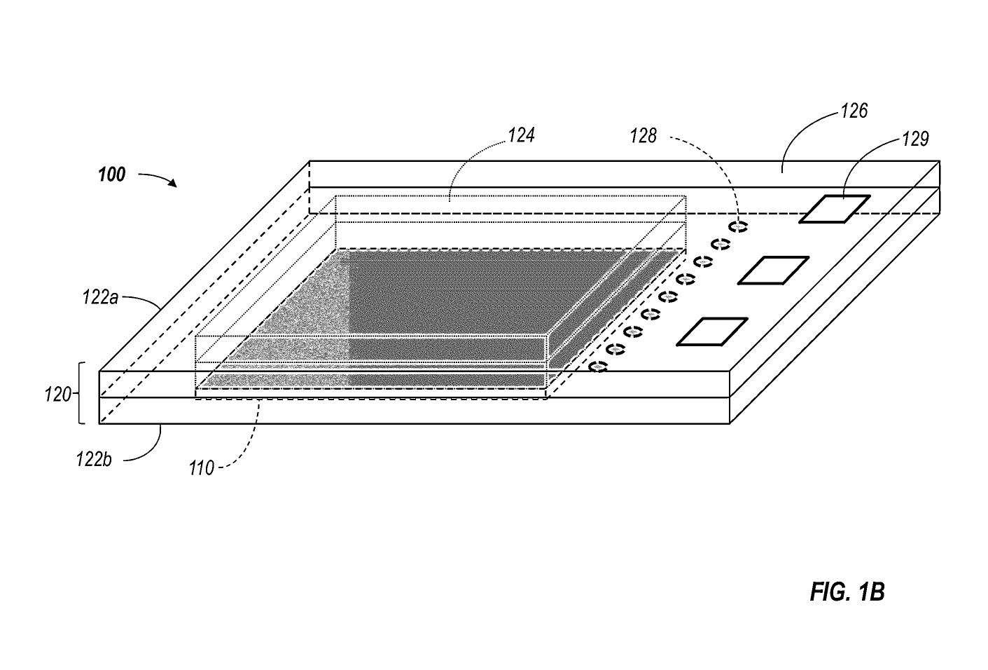

FIG. 1A shows an exploded view of a display device having an overlying multilayer laminate structure. The display device 100 includes a display 110 and a multilayer laminate structure 120 overlying the display device. In the illustrated implementation, multilayer laminate structure 120 includes two individual layers 122a and 122b adhered to one another via a substantially transparent adhesive (not shown). An internal region 124 of the multilayer structure 120 similar in dimensions to the underlying display 110 includes only light-transmissive components or components that are not readily distinguishable by a viewer, so that the view of the underlying display 110 is not obstructed.

A peripheral region 126 around one or more sides of the light-transmissive interior region 124 can include opaque or light-obstructing connection components, such as conductive bumps 128a configured to be brought into contact with facing bumps and/or bump connection regions 128b, bond pads or flex pads 129, or other structures that are configured to provide electrical communication between the individual layers 122a and 122b of the multilayer structure 120, as well as other components that may be internal or external to the display device 100.

In some implementations in which the connection components 128a and 128b are constrained to the peripheral region 126 of the display device 100, the size of the peripheral region 126 may be dependent at least in part by the inclusion of these connection components 128a and 128b. In some implementations, connection components may be provided at or along one or more edges of the multilayer structure 120.

FIG. 1B shows an assembled view of the display device of FIG. 1A. In particular, it can be seen that conductive bumps 128a (see FIG. 1B) on layer 122b have been brought into contact with the bump connection regions 128b on the facing surface of layer 122a to provide internal connectors 128 between layers 122a and 122b.

While conductive materials such as metals are generally opaque, in some implementations described below, materials that are optically transparent, are moderately conductive, and have substantial adhesive properties can be utilized in order to provide electrical connections in the form of conductive paths between electrically conductive elements on adjacent substrates while maintaining high viewability. Moderately conductive materials that are sufficiently thin can provide sufficient local conduction to provide electric communication between associated elements on adjacent facing substrates.

In contrast with anisotropic conducting films (ACF), these electrically conductive transparent adhesives (alternatively referred to herein as a transparent conductive adhesive, or TCA) need not have anisotropic conductive properties in which the conductivity in one direction is different than the conductivity in another direction. Rather, such transparent conductive adhesive materials can provide sufficient electrical isolation between adjacent (non-connected) elements even when using an unpatterned adhesive layer. This electrical isolation can be the result of the moderate conductivity of these layers, and can be improved by making the distance between adjacent conductive elements relatively large compared to the adhesive thickness. In some implementations, the TCA layer may be removed or omitted in regions between adjacent elements on the same substrate surface to further increase the electrical isolation.

Electrically conductive transparent adhesives can be made from formulations of polyfunctional adhesion promoters, chosen such that the functional group chemistry is suitable for a given pair of bonding surfaces. One example of a suitable material for use as an electrically conductive transparent adhesive in such implementations is 3-aminopropyldiethoxysilane (APTES), although other materials may also be used. APTES is a liquid at standard temperature and pressure (STP), and may be dissolved in water or acetone in a ratio of about 1 to 50% APTES by volume. In some implementations, the ratio may be about 4% APTES by volume, but ratios larger or smaller than 4% may also be used. A layer of APTES may be applied to a surface via any suitable process, including dip coating, spin coating, spray coating, or other dispensing methods. Adjacent surfaces may be bonded to one another by applying pressure, and the bonding process may be accelerated through the application of heat during the bonding process. For example, methods such as hot pressing, hot roll lamination, or clamping within an oven may be used to provide both pressure and heat. In some implementations, application of pressure at a temperature of about 80° C. for two hours or more provides sufficient adhesive strength, while at least 24 hours may be required at room temperature (about 25° C.). Other details and alternative fabrication methods are discussed in greater detail below.

The thickness of the optically transparent conductive adhesive layer may in some implementations be between about 1 and about 50 nm, although in other implementations thicknesses outside of this range may be used. The resistivity of the adhesive may be on the order of 1E3 to 1E7 Ω-cm, and in a particular implementation may be roughly 6 MΩ-cm. This level of resistivity may provide electrical isolation with separation as small as about 5 μm between adjacent conductive paths. For example, the contact resistance between two 100 μm×100 μm bond pads bonded with an unpatterned 5-nm thick conductive adhesive having a resistivity of 1E5 Ω-cm is about 500Ω in some implementations, whereas the electrical isolation between adjacent (non-connected) bond pads having a thickness of 1 um and a separation of 100 um is over 10 GΩ for dry-bonded substrates, and on the order of 500 MΩ for wet-bonded substrates.

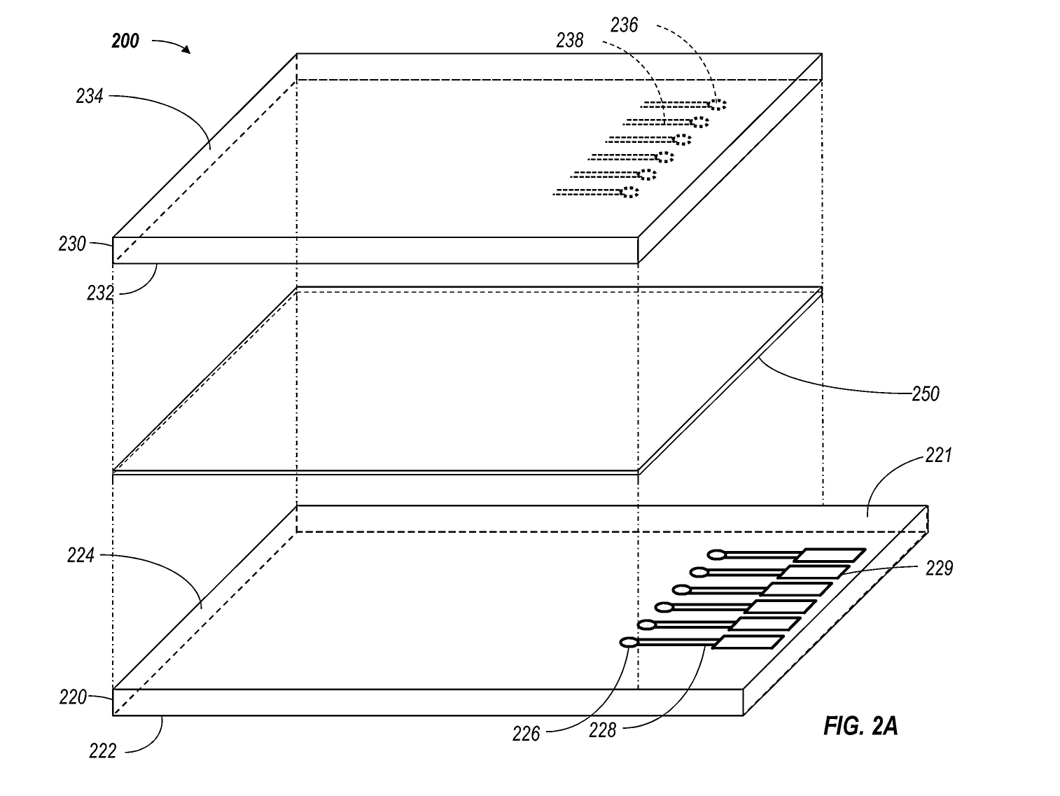

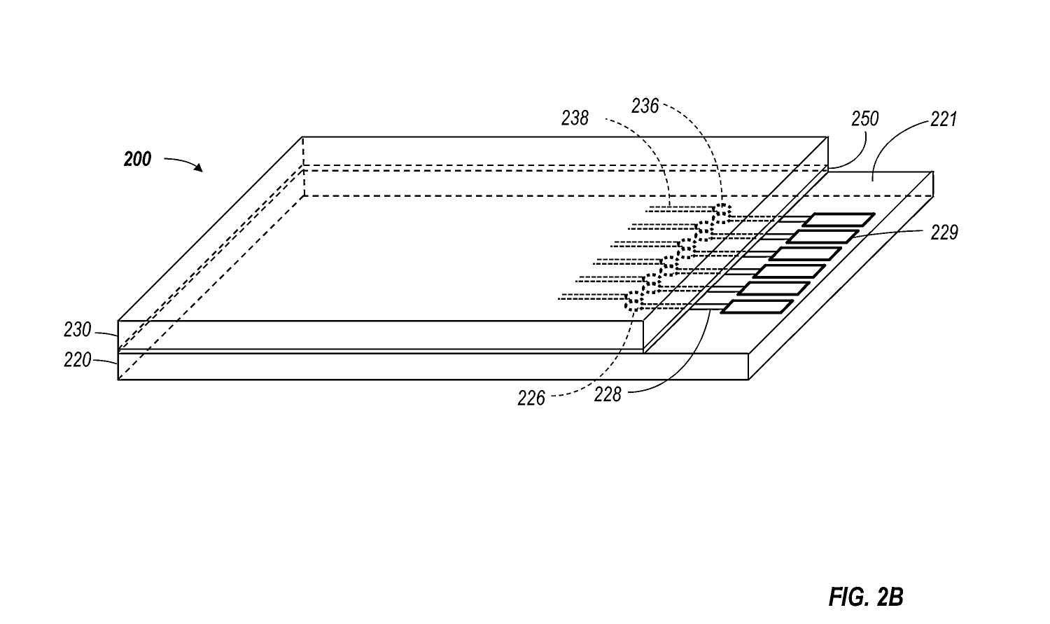

FIG. 2A shows an exploded view of a multilayer laminate structure that includes a pair of transparent substrates having electrically conductive structures formed thereon and bonded to one another by a thin transparent conductive adhesive material. The multilayer laminate structure 200 includes a first substrate 220 having a lower side 222 and an upper side 224, and a second substrate 230 having a lower side 232 and an upper side 234. A substantially transparent sheet or layer 250 of conductive adhesive material is disposed between the upper side 224 of the first substrate 220 and the lower side 232 of the second substrate 230.

Conductive components may be disposed on the inside or outside surfaces of the substrates 220 and 230. In the illustrated implementation, a plurality of conductive pads 226 in electrical communication with conductive traces 228 are disposed on the upper side 224 of the first substrate 220, and a plurality of conductive pads 236 in electrical communication with conductive traces 238 are disposed on the lower side 236 of the second substrate 230. The traces 228 disposed on the upper side 226 of the first substrate 220 may also be in electrical communication with an external bond pad or pads 229 disposed on an outwardly-extending ledge 221 of the first substrate 220.

At least a portion of the conductive components disposed on the first and second substrates 220 and 230 may be light-transmissive, or may be otherwise dimensioned, shaped, or masked so as to not be readily visible to a viewer. For example, the traces 238 disposed on the second substrate 230 may form or may be in electrical connection with transparent or masked electrodes within a capacitive touchscreen system. Similarly, additional traces (not shown) on the first substrate 220 may be in electrical connection with external bond pads 229 without terminating on an internal bond pad 226, but may instead form or extend to other conductive components disposed on the first substrate 220. In some implementations, the traces that extend into or across a display area are formed from transparent conductive materials such as indium tin oxide (ITO). In other implementations, such traces may be partially shielded from view by structures such as non-reflective masks or interferometric masks formed from a dark or black etalon, so as to reduce the optical effects caused by these traces.

Although illustrated as occurring to the side of the substrates for the purposes of clarity, the connections between facing conductive structures may be made anywhere across the surfaces of the facing layers. In particular, such connections may in some implementations be made within the portion of the substrates overlying the display, as discussed in greater detail herein.

FIG. 2B shows an assembled view of the multilayer laminate structure of FIG. 2A. The multilayer laminate structure 200 has been assembled by bonding the first transparent substrate 220 to the second transparent substrate 230 using the TCA layer 250. In particular, the internal bond pads 226 on the first substrate 220 have been brought into electrical communication with the internal bond pads 236 on the second substrate 230 via the TCA layer 250 disposed therebetween. Because the TCA layer 250 is thin, in some implementations between about one 1 nm and about 50 nm, sufficient electrical isolation (resistance) is obtained between adjacent (non-aligned) bond pads 226 on upper surface 224 of substrate 220 and adjacent (non-aligned) bond pads 236 on lower surface 232 of substrate 230, while each aligned pair of bond pads 236 and 226 have sufficiently low contact resistance that they are in electrical communication with one another. In some implementations, a ratio of the contact resistance between a facing pair of adjacent bond pads 234 and 236 and a resistance between adjacent bond pads 226 on substrate 230 may be less than about 1 to 1,000,000. In other implementations, this ratio may be greater or less than about 1 to 1,000,000. Similarly, sufficient electrical isolation is maintained between adjacent (non-overlapping) electrical traces 228 on surface 224 of substrate 220 and adjacent (non-overlapping) traces 238 on surface 232 of substrate 230. Although schematically illustrated as being similarly dimensioned to the associated traces 228 and 238, bond pads 226 and 236 may be enlarged relative to the thicknesses of the associated traces 228 and 238 to further decrease the contact resistance and to facilitate alignment accuracy during bonding.

Thus, although the TCA layer 250 is unpatterned and need not have anisotropic conductive properties, sufficient electrical isolation is provided between adjacent pairs of overlapping bond pads 226 and 236 and adjacent traces 228 and 238. This electrical isolation is due to the thinness of the TCA layer 250 and the comparatively larger spacing between adjacent conductive components on each substrate 220 and 230, along with the intermediate conductivity of the TCA layer 250.

As can also be seen in FIG. 2B, the assembled multilayer laminate structure 200 may be formed from substrates 220 and 230 that are of different sizes or are misaligned relative to one another in order to provide one or more outwardly extending ledges on or both of the substrates in the finished assembly 200, such as outwardly extending ledge 221 of substrate 220. Such outwardly extending ledges provide a location for external bond pads 229 that are exposed in the finished assembly. A flex tape or similar structure (not shown) can be used to contact the external bond pads 229, using the TCA 250, or using conventional flex-tape bonding procedures such as those that incorporate solder or anisotropic conductive film. In some configurations, the flex tape can make electrical connections directly or indirectly to devices or features on either substrate 220 or 230 while only in direct physical contact with one of the substrates 220 and 230, reducing the complexity and number of flex tapes in a finished device incorporating the multilayer assembly 200.

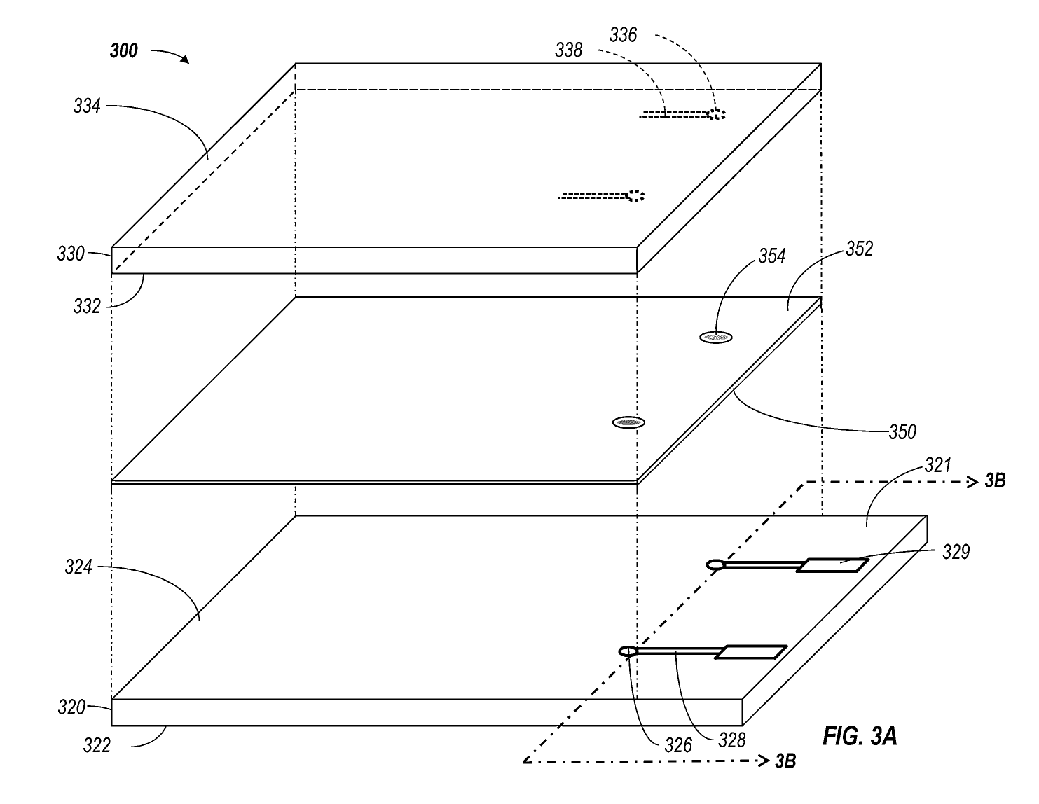

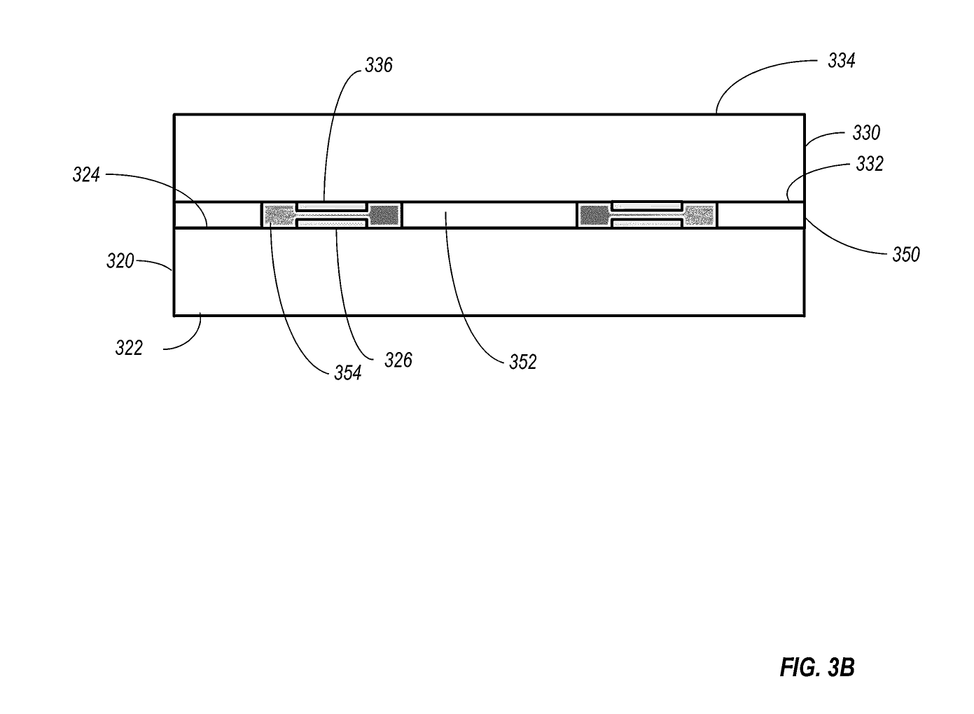

Although an unpatterned TCA layer can in some implementations provide sufficient isolation between adjacent conductive components to provide a plurality of functionally isolated conductive paths between assembled substrates, this electrical isolation can be further enhanced by patterning the TCA layer. FIG. 3A shows an exploded view of a multilayer laminate structure that includes a combination of conductive and substantially non-conductive (or less conductive) transparent adhesives to adhere two substrates to one another.

The assembly 300 of FIG. 3A is similar in structure to the assembly 200 of FIGS. 2A and 2B, except that the adhesive layer 350 of assembly 300 includes sections of TCA 354 separated from one another by sections of transparent non-conductive or less conductive adhesive 352. In the illustrated implementation, two sets of internal bond pads 326 and 336 (and associated traces 328 and 338) are depicted for clarity, although any number of sets of internal bond pads 326 and 336 may be provided in other implementations. Note also that while bond pads 326 and 336 are shown near a periphery of substrates 320 and 330, the bond pads 326 and 336 and associated traces 328 and 338 may be positioned elsewhere on the substrates 320 and 330.

The layer 350 of adhesive materials includes discrete sections 354 of TCA material aligned with corresponding pairs of internal bond pads 326 and 336, such that the TCA portions 354 of the adhesive layer 350 form an electrical connection in the form of a conductive path between the internal bond pads 326 and 336 in each set of aligned bond pads. However, because the adhesive layers 350 include sections 352 of non-conductive or less conductive adhesive material between the TCA portions 354, the lateral electrical isolation between the adjacent pairs of internal bond pads 326 and 336 is increased.

The inclusion of non-conductive adhesive sections 352 can also increase the overall adhesion strength and allow improved index matching between the substrates 320 and 330, by selecting non-conductive adhesives with a higher adhesion strength and an index of refraction that matches more closely to the refractive index of the substrates. In some implementations, the non-conductive or less conductive adhesive sections 352 may be formed from a material having similar optical properties as the material forming the TCA sections 354. In certain implementations of optical devices such as displays, the TCA 354 and the less-conductive adhesive 352 may have similar or identical indices of refraction.

This increase in lateral electrical isolation can be used, for instance, to provide increased electrical isolation between conductive paths on the substrates 320 and 330, and/or to lessen the manufacturing and/or design constraints necessary to provide a similar level of electrical isolation as would be provided with a thin unpatterned conductive transparent adhesive layer. While in the illustrated implementation, the spaces between the sections 354 of the patterned TCA layer 350 are filled with a non-conductive or less conductive transparent adhesive, in other implementations these intervening sections may be left unfilled or empty, further increasing the electrical isolation of the conductive paths formed within the TCA sections 354. In other implementations, some portion of the areas between the TCA sections 354 may be filled with non-conductive or less conductive adhesive sections 352, while other areas between TCA sections 354 may be left unfilled.

FIG. 3B shows a cross-section of the assembled multilayer structure of FIG. 3A, taken along the line 3B-3B. In particular, it can be seen that the overlying pairs of internal conductive pads 326 and 336 are placed in electrical communication with one another via a thin portion of TCA section 354 disposed therebetween. The conductive adhesive section may in some implementations be wider than the overlapping portions of the facing conductive components to reduce alignment constraints and ensure that the components are placed in electrical communication with each other with a minimum amount of contact resistance.

Although schematically depicted as circles extending beyond pads 326 and 336 for clarity, the TCA sections 354 can be patterned to form any desired shape such as squares, rectangles, or stripes. In some implementations, each TCA section 354 corresponds to a single pair of conductive elements, while in other implementations, a given TCA section 354 may form electrical connections between more than one pair of conductive elements, or may serve only an adhesive function and connect no conductive elements.

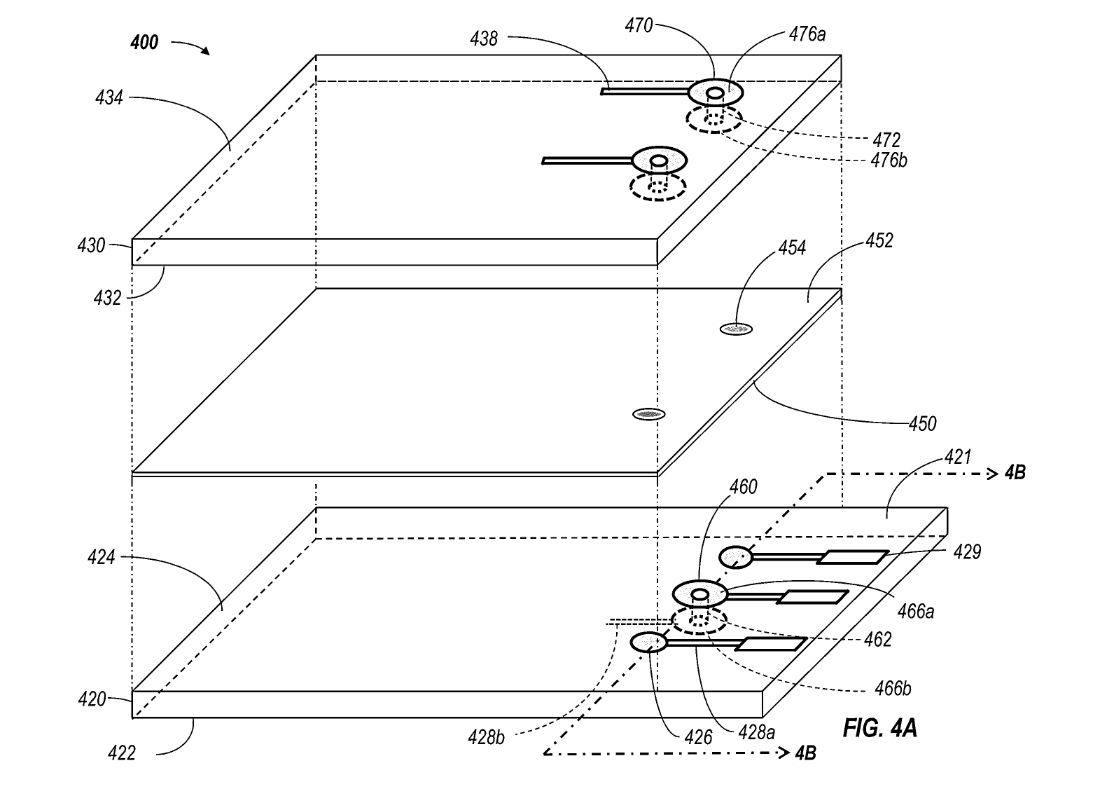

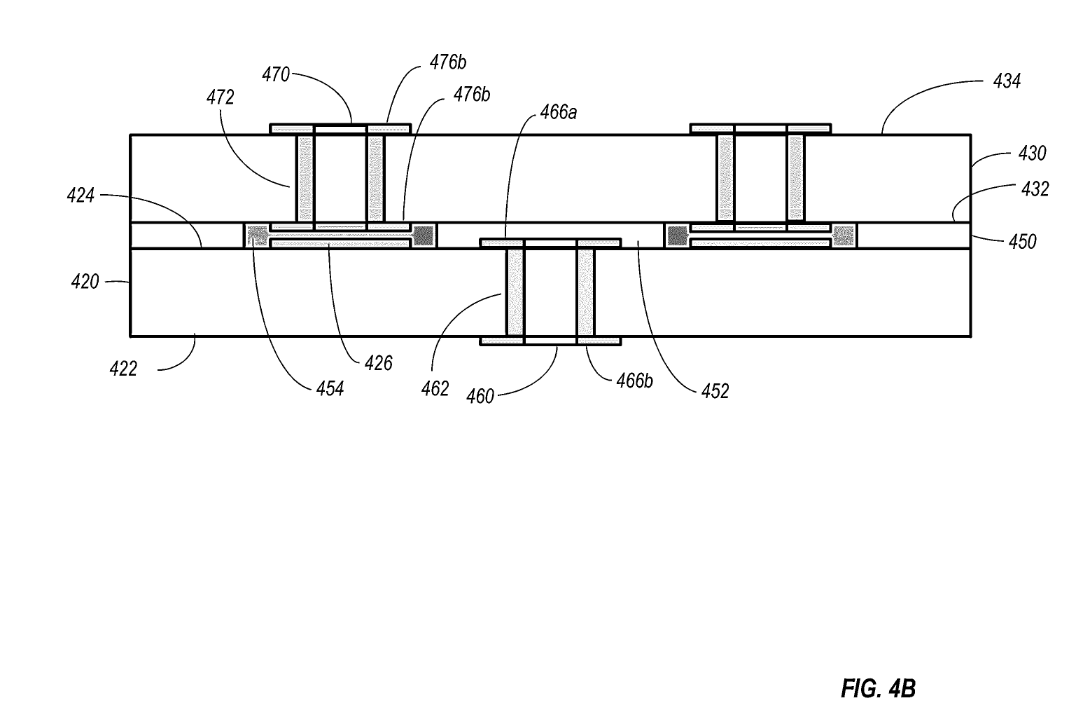

In addition to forming connections between conductive components on facing surfaces of assembled substrates, transparent conductive adhesives can be used in conjunction with transparent or non-transparent conductive vias extending through a substrate to allow electrical connections with any layer. FIG. 4A shows an exploded view of a multilayer laminate structure that includes conductive vias that enable electrical connections through the component substrates. The assembly 400 of FIG. 4A includes a first substrate 420, a second substrate 430, and a layer 450 of adhesive materials disposed therebetween. The layer 450 of adhesive materials includes one or more sections 454 of TCA, and one or more sections 452 of less conductive or substantially non-conductive transparent adhesive. An external bond pad 429 is disposed on the upper surface 424 of substrate 420, and in the illustrated implementation is disposed on a laterally extending ledge 421 to facilitate an external connection with the assembly 400. Conductive traces 428a extend from the external bond pad 429 to both internal bond pads 426 and at least one conductive via 460 extending through the substrate 420.

The conductive via 460 includes a section 462 of conductive material extending through the substrate 420 between a conductive section 466a on the upper surface 424 of the substrate 420 and a conductive section 466b on the lower surface 422 of the substrate 420. The conductive section 466b on the lower surface 422 of the substrate 420 is in electrical communication with a conductive trace 428b on the lower surface 422 of the substrate 420 through conductive section 462. The conductive via 460 allows a bond pad 429 on one surface 424 to provide electrical connection with both surfaces 422 and 424 of substrate 420. In some implementations, these vias may be referred to as through-glass vias (TGVs) or through-substrate vias (TSVs). The vias may be transparent or non-transparent. In the illustrated implementation, the conductive sections 466a and 466b take the form of radially extending flanges, although in other implementations, these sections 466a and 466b may be asymmetrical, square, rectangular, or other suitable shape. In some implementations, traces 428a and 428b may connect directly to the conductive section 462 extending through the substrate 420.

One or more internal bond pads 426 on the first substrate 420 may be aligned with conductive vias 470 extending through the second substrate 430. In particular, the conductive vias 470 include a section 472 of conductive material extending through the substrate 430 between a conductive section 476a on the upper surface 434 of the substrate 430 and a conductive section 476b on the lower surface 432 of the substrate 430. In particular, the transparent conductive adhesive sections 454 may form electrical connections between the internal bond pads 426 on the upper surface 424 of the first substrate 420 and the conductive section 476b on the lower surface 432 of the substrate 430. Conductive traces 438 on the upper surface 434 of second substrate 430 may extend from the conductive sections 476a of the vias 470. The conductive vias 460 and 470 allow one or more bond pads 429 on a single surface 424 of the multilayer assembly 400 to provide electrical communication with one or more conductive components disposed on any other surface within the multilayer assembly 400.

FIG. 4B shows a cross-section of the assembled multilayer structure of FIG. 4A, taken along the line 4B-4B. As can be seen in FIG. 4B, the TCA sections 454 do not extend over the conductive via 460 extending through substrate 420, such that the conductive via 460 is electrically isolated from the internal bond pads 426 and the conductive vias 470.

The illustrated implementation the conductive sections 462 and 472 of vias 460 and 470 include an annular pillar of conductive material extending along the sides of an aperture through the substrates 420 and 430, respectively. In other implementations, however, the conductive sections 462 and 472 may include a solid plug of material, or may take any other appropriate shape. In some implementations, portions or all of the conductive sections 462 and 472 may be transparent or non-transparent.

In further implementations, structures may be formed that include an electrical communication path between any surfaces within a multi-layer structure of two or more assembled layers or substrates, and which can interconnect conductive structures such as electrical traces, conductive vias, bond pads, and electrical or electronic devices formed on any of these structures. Because the use of TCA allows the formation of such connections even in areas of a structure overlying a display, these conductive structures may be combined in any suitable arrangement.

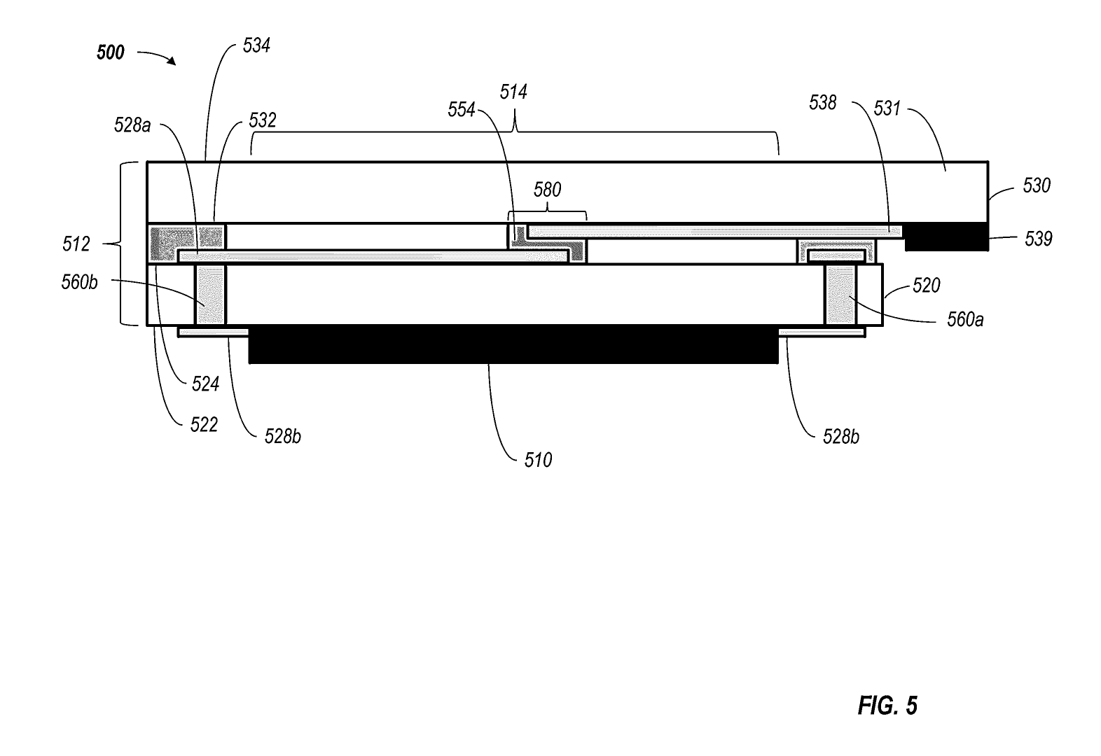

FIG. 5 shows a cross-section of a display device in which transparent conductive material provides an electrical connection between substrates within a multilayer assembly. The display device 500 includes a display 510 and an overlying multilayer assembly 512 through which the display 510 is viewable. The multilayer assembly 512 includes a first substrate 520 having an lower surface 522 adjacent the display 510 and an upper surface 524, and a second substrate 530 having a lower surface 532 adjacent the upper surface 524 of substrate 520, and an upper surface 534.

A flex pad 539 is disposed on the lower surface 532 of substrate 530, on an outwardly extending ledge 531 of the substrate 530. A plurality of traces 538 (schematically depicted as a single trace for the purposes of clarity) extend along the lower surface 532 of substrate 530. One or more traces 538 may be electrically connected to the flex pad 539. Opposing the trace 538 are a through-substrate via 560a and a conductive trace 528a on the upper surface 522 of substrate 520. Sections 554 of transparent conductive adhesive place one traces 538 in electrical communication with the via 560a, and one or more traces 538 in electrical communication with one or more opposing traces 528a.

In particular, it can be seen that the electrical connection 580 formed by the TCA section 554 disposed between the trace 538 and the opposing trace 528a is within the viewable area 514 of the underlying display 510. Because the TCA material 554 is substantially transparent, and in some implementations may be index matched to the adjacent layers, the electrical connection 580 may not have a noticeable impact on the appearance of the underlying display 510.

As noted above, in some implementations, the portions of the traces 538 and 528a extending across the viewable area of the display device are transparent, while in other implementations, the traces 538 and 528a may not be transparent, but may instead be masked or may be sized or shaped to not be readily apparent to a viewer. Even when the portions of the traces 538 and 528a extending adjacent one another are not transparent, the use of a TCA material to connect the two may be beneficial. The TCA material 554 may extend laterally beyond the overlapping portions of the traces 538 and 528a, thus facilitating alignment and connection between the traces 538 and 528a. Because the TCA material 554 is substantially transparent, the TCA material 554 can be made larger in area than the overlapping portions of the traces 538 and 528a, reducing the necessary alignment precision in patterning or selectively depositing the TCA material 554 relative to the traces 538 and 528a.

In the illustrated implementation, the trace 528a connects to a via 560b extending through the substrate 520, and each of vias 560a and 560b are connected to the display 510 via one or more traces 528b. Thus, a single flex pad region or array of flex pads 539 at a single location may be used to provide multiple connections with the display 510 or other electrical component within or adjacent the multilayer structure 512, using electrical connections routed throughout the multilayer structure 512. Through the use of TCA material between the component substrates, electrical connections 580 or vias 560a and 560b can even be made within or peripheral to the display area 514 of the display device 500.

Although not specifically depicted herein, connections through multiple substrates may be provided by aligning vias in a first substrate with vias in a second facing substrate. In some implementations, at least the facing portions of such in-line vias may include an outwardly extending flange portion to further reduce contact resistance and improve alignment. In some implementations, connections through multiple substrates may be provided by vias that are staggered and connected to one another using traces extending between one or both of the facing substrates.

Any number of additional substrates can be incorporated into the multilayer structure 512, to provide more complex devices and structures. For example, the multilayer structure 512 may include ground planes, touchscreen arrays, a cover glass, optical films such as light-turning films, electrostatic shields, or other device component. In some implementations, multiple separate multilayer structures 512 can be disposed between other components in a larger stack of layers. In some implementations, one or more components may be disposed between multiple separate multilayer structures 512.

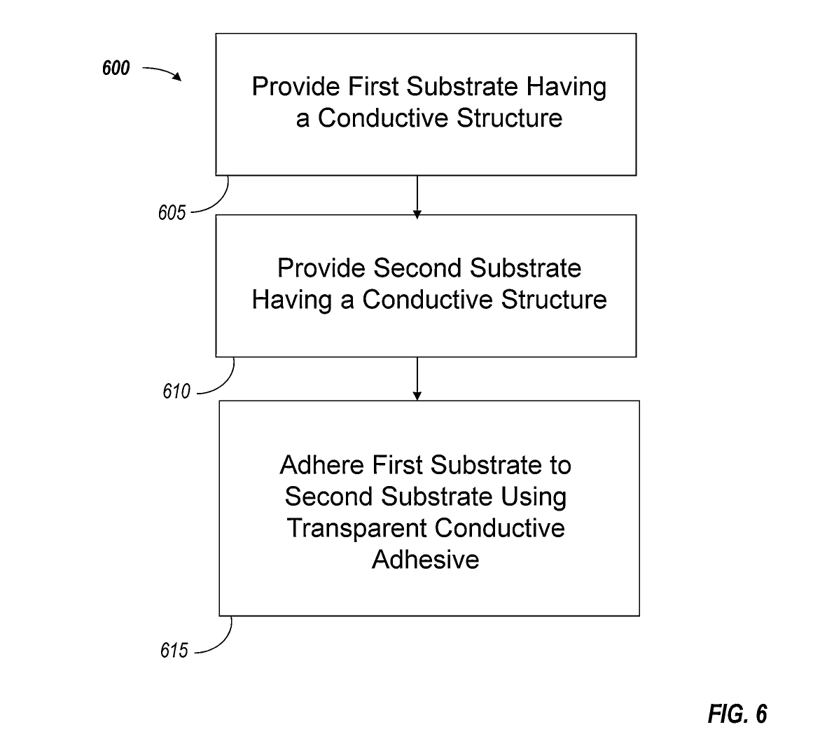

FIG. 6 shows an example of a flow diagram illustrating a manufacturing process for a multilayer assembly including transparent conductive material for providing an electrical connection between substrates within the assembly. The method 600 begins at a block 605 where a substantially transparent first substrate is provided, the first substrate including a first surface having a first conductive structure disposed on a surface of the substrate. As discussed above, these conductive structures may include one or more electrical traces, connection pads, or any other suitable conductive structure, and at least a portion of the conductive structures may be substantially transparent or otherwise not readily distinguishable by a viewer due to its size, shape, and/or use of masking structures.

The method 600 moves to a block 610 where a substantially transparent second substrate is provided, the second substrate including a first surface facing the first surface of the first substrate and having a second conductive structure disposed on a surface of the substrate. The second substrate may be different in size than the first substrate, such that a portion of one of the substrates may extend laterally outward beyond at least one edge of the other substrate when the substrates are adhered to one another.

The method 600 moves to a block 615 where the first substrate is adhered to the second substrate using a transparent conductive adhesive disposed between the first conductive structure and the second conductive structure. In addition to providing at least part of the adhesion holding the two substrates together, the TCA also provides an electrically conductive path between the first conductive structure and second conductive structure. In some implementations, a non-conducting transparent adhesive may be used to adhere portions of the substrates together.

The blocks of method 600 are merely exemplary, and implementations of various manufacturing processes may perform the steps discussed above in a different order, may include additional steps, or may omit certain steps, or may combine steps illustrated as separate blocks in FIG. 6. For example, the adhesion process may be varied in several ways in a variety of implementations.

In some implementations, the TCA material may be disposed on or applied to one or both of the substrates prior to bonding the two substrates together. As discussed above, the application of the TCA material may be done via any suitable process, including but not limited to spin-coating, dispensing, dipping, or spraying. The two substrates may be bonded to one another before the TCA material is cured in a wet-bonding process, or after the TCA material is cured or partially cured in a dry-bonding process.

In an implementation in which the TCA is applied to only one of the two substrates to be bonded together, the composition of the two substrates may be taken into account if the two substrates are formed from different materials, in order to determine to which substrate the TCA material should be initially applied. For example, for certain TCA materials, such as APTES, the dispensed or applied TCA may adhere more readily to a glass, silicon oxide, or silicon substrate than to a metallic surface, or to a substrate such as a polymide insulation (PI) film such as Kapton® or Neopulim®, a polyester (PET) film, or a polycarbonate (PC) substrate.

The adhesion of the TCA material to the substrates can be improved by treating the substrates prior to application of the TCA material, or prior to bonding an opposing substrate to a layer having TCA dispensed or applied thereon. This process may alternatively be referred to as a surface activation process. In some implementations, this surface activation process may include exposure of the substrate to an ultraviolet-ozone (UVO) or oxygen plasma (O₂-plasma) treatment process for a given period of time. In some implementations, the substrate may be exposed to the UVO or O₂-plasma treatment for roughly five minutes, although longer and shorter exposure times may also be used. In particular implementations, the UVO or O₂-plasma treatment may be used to treat glass, silicon oxide, and silicon substrates, although surface activation processes can also be used on other substrate materials as well.

As noted above, the bonding process may differ in various implementations. In some implementations, the bonding process may be performed at room temperature, roughly 25° C., or may be performed at higher temperatures, such as temperatures as high as or higher than about 200° C. At room temperature in some implementations, the bonding process may take roughly four hours, while this time may be reduced at higher temperatures. For example, by increasing the temperature to 80° C. during the bonding process, the bonding time can be cut in half to roughly two hours. Further increasing the temperature can further accelerate the bonding process.

In addition, pressure may be applied during the bonding process. In some implementations, this pressure may be applied by clamping the two substrates together, whether directly or between additional substrates. In other implementations, a hot press or a hot roll lamination process can be used to apply both heat and pressure during the bonding process. In some implementations, the pressure applied can be greater than about 0.1 psi, although in other implementations, more or less pressure may be applied. In some implementations, such as during a hot roll lamination process, the pressure may only be applied to a portion of the substrate at any given time, or may be applied for only a portion of the total bonding time.

While the above description has generally discussed the bonding of two substrates together, any number of substrates greater than two can be incorporated into the multilayer laminate structures discussed herein. In some implementations, additional substrates may be bonded sequentially to one another, while in other implementations, several substrates may be simultaneously bonded to one another.

In some implementations in which discrete sections of TCA material are formed or applied to a substrate, the TCA material may in some implementations be deposited or applied in a blanket layer, and subsequently patterned to remove sections of TCA material in a desired pattern. In other implementations, the TCA may be selectively deposited or applied in a desired pattern. Subsequent to the formation of TCA sections in a desired pattern, the spaces between TCA sections may be left unfilled, or may be filled with a less-conductive or substantially non-conductive adhesive, or may be filled with a non-adhesive material. Examples of non-conductive adhesives can include any of a range of optical coupling adhesives (OCAs) or other transparent adhesives that minimize the refractive index difference between the substrate materials and the adhesive. Examples of non-adhesive materials can include transparent fluids, such as silicone, hydrocarbon, or fluorocarbon fluids, or polymer resins and gels. In other implementations, such additional material may be deposited before the TCA, with the TCA material being deposited or applied in the regions between the additional material.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

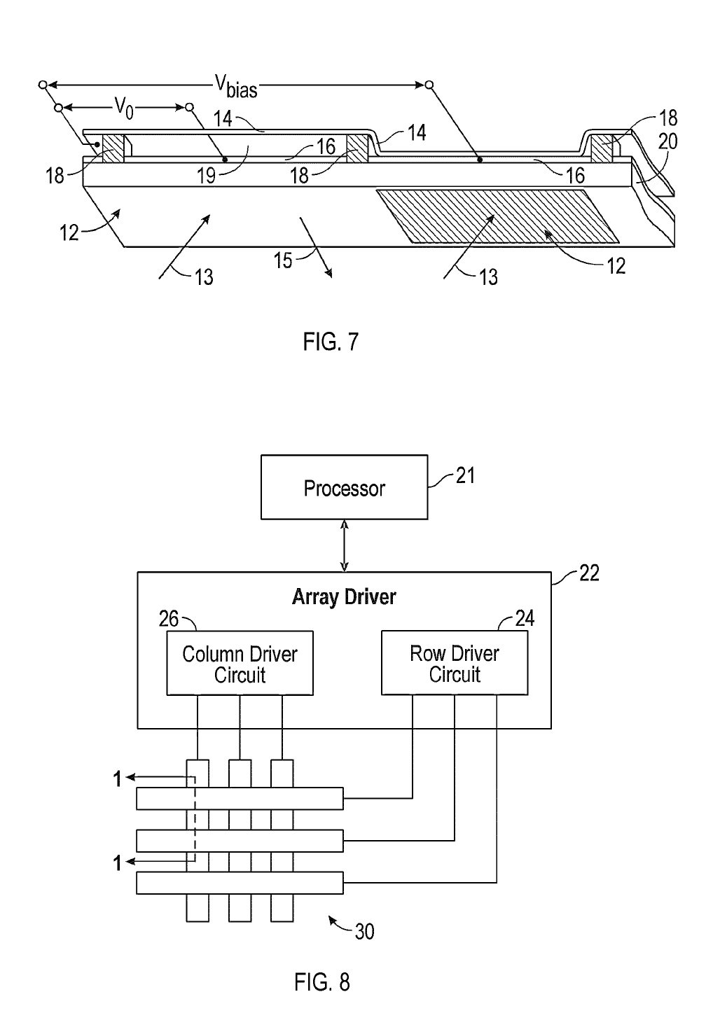

FIG. 7 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements that may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 7 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage Vₒ applied across the display element 12 on the left is insufficient to cause actuation of the movable reflective layer 14 to an actuated position such as that of the display element 12 on the right.

In FIG. 7, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer that is partially transmissive and partially reflective, may be configured to be viewed from the opposite side of a substrate as the display elements 12 of FIG. 7 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor that serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 7, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 7. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 8 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 7 is shown by the lines 1-1 in FIG. 8. Although FIG. 8 illustrates a 3×3 array of IMOD display elements for the sake of clarity, the display array 30 may contain a very large number of IMOD display elements, and may have a different number of IMOD display elements in rows than in columns, and vice versa.

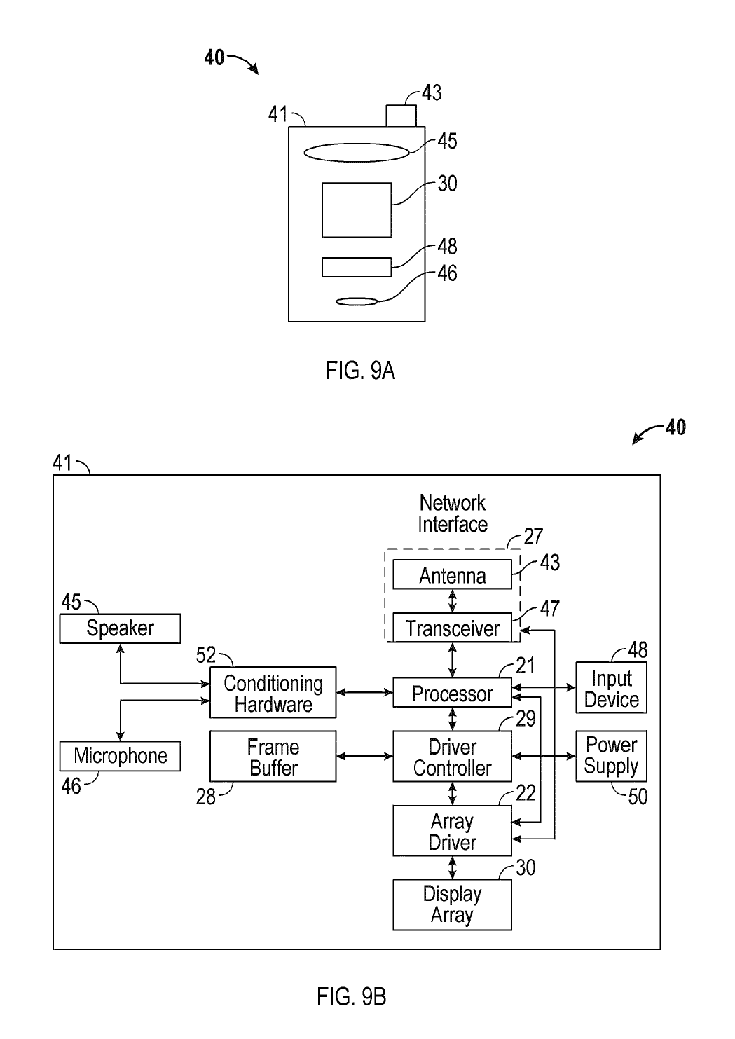

FIGS. 9A and 9B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 9A. The display device 40 includes a housing 41 and can include additional components at least partially enclosed therein. For example, the display device 40 includes a network interface 27 that includes an antenna 43 that can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone integrated circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 that can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

For example, although the operation of IMOD-based displays is discussed in detail above, implementations discussed above may be used in conjunction with any display or other object to be viewed through a light-transmissive multilayer assembly. For example, any display, whether reflective or emissive, including but not limited to LCD, LED, OLED, e-ink, or any other display type, may be used in conjunction with the implementations described above. The above implementations may be used in any type of display devices, including but not limited to cell phones, tablet computers, touchscreens, or e-readers.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A multi-layer device, comprising:
a substantially transparent first substrate, the first substrate including a first surface having a first conductive structure formed thereon;
a substantially transparent second substrate, the second substrate including a first surface facing the first surface of the first substrate and having a second conductive structure formed thereon; and
a transparent conductive adhesive layer adhering the first substrate to the second substrate, wherein the transparent conductive adhesive layer is disposed between at least a portion of the first conductive structure and at least a portion of the second conductive structure and provides a first conductive path therebetween.

2. The device of claim 1, wherein the first conductive structure and the second conductive structure include a transparent conductive material.

3. The device of claim 1, wherein the first conductive structure includes a first bond pad in electrical communication with a first conductive trace on the first surface of the first substrate, and wherein the second conductive structure includes a second bond pad in electrical communication with a second conductive trace on the first surface of the second substrate.

4. The device of claim 1, wherein the first conductive structure includes a conductive via extending through the first substrate.

5. The device of claim 1, further including a third conductive structure on the first surface of the first substrate and a fourth conductive structure on the first surface of the second substrate, wherein the transparent conductive adhesive layer is disposed between at least a portion of the third conductive structure and at least a portion of the fourth conductive structure and provides a second conductive path therebetween, the second conductive path being electrically isolated from the first conductive path.

6. The device of claim 5, wherein a first portion of the transparent conductive adhesive layer disposed between the first and second conductive structures is separated from a second portion of the transparent conductive adhesive layer disposed between the third conductive structure and the fourth conductive structure.

7. The device of claim 5, wherein a ratio of a resistance between the first and third conductive structures and a contact resistance between the first and second conductive structures is greater than about 1,000,000.

8. The device of claim 1, wherein the transparent conductive adhesive layer includes one or more polyfunctional adhesion promoters.

9. The device of claim 1, wherein the transparent conductive adhesive includes 3-aminopropyldiethoxysilane (APTES).

10. The device of claim 1, wherein the transparent conductive adhesive includes a material having a resistivity of between about 1,000 and about 10,000,000 ohm-cm.

11. The device of claim 1, wherein a thickness of a portion of transparent conductive adhesive between the first and second conductive structures is less than about 50 nm.

12. The device of claim 1, wherein the contact resistance between the first conductive structure and the second conductive structure is less than about 10,000 ohms.

13. The device of claim 1, additionally comprising a display, wherein the display is viewable through the first transparent substrate and the second transparent substrate.

14. The device of claim 13, wherein the display includes one of a light emitting diode based display, an organic light emitting diode based display, a liquid crystal display, a field emission display, an e-ink display, and an interferometric modulator based display.

15. The device of claim 13, wherein the first conductive path between the first conductive structure and the second conductive structure overlies at least a portion of the display.

16. The device of claim 13, additionally including:
a processor that is configured to communicate with the display, the processor being configured to process image data; and
a memory device that is configured to communicate with the processor.

17. The device of claim 16, additionally including:
a driver circuit configured to send at least one signal to the display; and
a controller configured to send at least a portion of the image data to the driver circuit.

18. The device of claim 16, additionally including an image source module configured to send the image data to the processor, wherein the image source module includes at least one of a receiver, transceiver, and transmitter.

19. The device of claim 16, additionally including an input device configured to receive input data and to communicate the input data to the processor.

20. A method of fabricating a multi-layer device, comprising:
providing a substantially transparent first substrate, the first substrate including a first surface having a first conductive structure formed thereon;
providing a substantially transparent second substrate, the second substrate including a first surface facing the first surface of the first substrate and having a second conductive structure formed thereon; and
adhering the first substrate to the second substrate using a transparent conductive adhesive disposed between the first conductive structure and the second conductive structure, wherein the transparent conductive adhesive provides an electrically conductive path between the first conductive structure and second conductive structure.

21. The method of claim 20, wherein adhering the first substrate to the second substrate includes:
coating at least a portion of the first surface of the first substrate with the transparent conductive adhesive; and
bonding the first surface of the first substrate to the first surface of the second substrate.

22. The method of claim 21, wherein the transparent conductive adhesive is at least partially cured prior to bonding the first surface of the first substrate to the first surface of the second substrate.

23. The method of claim 21, wherein the transparent conductive adhesive is cured after bringing the first surface of the first substrate into contact with the first surface of the second substrate.

24. The method of claim 21, wherein coating at least a portion of the first surface of the first substrate with the transparent conductive adhesive includes forming discrete sections of transparent conductive adhesive on the first surface of the first substrate.

25. The method of claim 24, additionally including forming sections of a second material between the discrete sections of transparent conductive adhesive, wherein the second material is less conductive than the transparent conductive adhesive.

26. The method of claim 24, wherein at least a portion of the space between the discrete sections of transparent conductive adhesive is left unfilled.

27. The method of claim 20, wherein adhering the first substrate to the second substrate includes applying pressure to hold the first and second substrates together.

28. The method of claim 27, wherein adhering the first substrate to the second substrate additionally includes exposing the first and second substrates to a temperature between about 25° C. and about 200° C.

29. The method of claim 20, additionally including performing a surface activation process to treat at least one of the first surface of the first substrate or the first surface of the second substrate prior to adhering the first substrate to the second substrate.

30. The method of claim 29, wherein performing the surface activation process includes exposing at least one of the first surface of the first substrate or the first surface of the second substrate to an ultraviolet ozone treatment or an oxygen plasma treatment.

31. A display device, comprising:
a display; and
a multilayer structure overlying the display, wherein the display is configured to be visible through a portion of the multilayer structure, the multilayer structure including:
a first substrate, wherein at least a portion of the first substrate overlying the display is substantially transparent;
a second substrate, wherein at least a portion of the second substrate overlying the display is substantially transparent; and
a transparent conductive adhesive disposed between at least a portion of the first substrate and the second substrate; wherein the transparent conductive adhesive forms a conductive path between at least a portion of a first conductive structure disposed on the first substrate and at least a portion of a second conductive structure disposed on the second substrate.

32. The device of claim 31, wherein the multilayer structure additionally includes an external bond pad disposed on a first surface of the first substrate, and wherein the external bond pad is in electrical communication with the first conductive structure.

33. The device of claim 32, wherein the multilayer structure additionally includes a third conductive structure disposed on the second substrate, wherein the second and third conductive structures are disposed on opposite sides of the second substrate, and wherein the second and third conductive structures are electrically connected to one another by a conductive via extending through the second substrate.

34. The device of claim 31, wherein the conductive path between the first conductive structure and the second conductive structure is located within the portion of the multilayer structure through which the display is configured to be visible.
